(19) United States
(12) Patent Application Publication
(10) Pub. No.: US 2026/0117375 A1
(43) Pub. Date: Apr. 30, 2026

(54) VAPOR PHASE GROWTH APPARATUS

(71) Applicant: TAIYO NIPPON SANSO CORPORATION, Tokyo (JP)

(72) Inventors: Shuuichi KOSEKI, Tokyo (JP); Sadahiro YAMADA, Tokyo (JP)

(21) Appl. No.: 19/142,501

(22) PCT Filed: Dec. 27, 2023
(86) PCT No.: PCT/JP2023/047104

§ 371 Date: Jun. 23, 2025

(51) Int. Cl. C23C 16/448; H10P 14/24

(52) U.S. Cl. CPC C23C 16/4481; H10P 14/24

(57) ABSTRACT

The vapor phase growth apparatus of the present invention supplies a raw material gas obtained by transporting vapor of an organometallic raw material by a carrier gas into a reactor. The carrier gas is supplied into a container filled with an organometallic raw material, and the carrier gas transports vapor of the organometallic raw material to produce the raw material gas. In a carrier gas supply line upstream of the container, a heater is provided between a mass flow controller that controls the supply amount of the carrier gas and the container storing the organometallic raw material to heat the carrier gas in the carrier gas supply line. In the case where a raw material gas dilution line that supplies the carrier gas into the raw material gas supply line downstream of the container is provided, a second gas heater that heats the carrier gas in the raw material gas dilution line is further provided downstream of the second mass flow controller that controls the supply amount of the carrier gas in the raw material gas dilution line.

### TECHNICAL FIELD

The present invention relates to a vapor phase growth apparatus.

### BACKGROUND ART

Conventionally, in a vapor phase growth apparatus for forming a compound semiconductor thin film on a substrate, as a method for supplying an organometallic raw material to the substrate, a method in which nitrogen gas or hydrogen gas is supplied as a carrier gas into a container filled with the organometallic raw material, and the carrier gas transporting vapor of the organometallic raw material is discharged from the container filled with organometallic raw material and supplied into a reactor is commonly used (For example, Patent Document 1).

In the vapor phase growth apparatus, the following raw material gas supply device is used to form a compound semiconductor thin film on a substrate in a reactor. In the raw material gas supply device, vapor of the organometallic raw material is transported by a carrier gas to form a raw material gas, and the raw material gas produced is supplied into a reactor. In the raw material gas supply device, nitrogen, hydrogen gas, or other gas is supplied as the carrier gas into a container filled with the organometallic raw material. The vapor of the organometallic raw material is transported by the carrier gas to produce a raw material gas, which is then led out from the container and supplied into the reactor.

When the raw material gas is supplied into the reactor, its vapor pressure depends on its temperature. In order to constantly supply the organometallic raw material, the organometallic raw material must be supplied while being maintained at a specified temperature. For this reason, for example, a container filled with the organometallic raw material may be placed in a thermostatic bath. In order to constantly supply the organometallic raw material, it is necessary to keep not only the temperature but also the flow rate of the carrier gas and the pressure inside the container of the organometallic raw material constant.

Therefore, when the vapor pressure of the organometallic raw material is low or when a large amount of the organometallic raw material needs to be supplied, it is necessary to ensure the supply of the organometallic raw material by maintaining the temperature of the organometallic raw material at a relatively high level.

For example, a heater could be provided in the mass flow controller that controls the supply of the carrier gas to heat the carrier gas. However, since the mass flow controller is an electronic device, it becomes impossible to control the flow rate when it is heated to a high temperature. In addition, when the temperature of the container of the organometallic raw material becomes higher than the heating temperature of the mass flow controller, the following problem occurs. That is, a relatively low-temperature carrier gas is supplied into a container of the organometallic raw material, which is maintained at a high temperature. This causes the temperature inside the container to drop, making vapor of the organometallic raw material unstable, resulting in an insufficient supply of the organometallic raw material. Furthermore, when the temperature inside a pipe downstream of the container drops, the organometallic raw material, which has a low vapor pressure, condenses, making it impossible to supply the appropriate amount of the organometallic raw material into the reactor.

### PRIOR ART DOCUMENTS

### Patent Documents

Patent Document 1: Japanese Unexamined Patent Application, First Publication No. 2002-313731

### SUMMARY OF INVENTION

### Problem to be Solved by the Invention

The present invention provides a vapor phase growth apparatus that can stably supply a raw material gas into a reactor even when the vapor pressure of the organometallic raw material is low or when a large amount of the organometallic raw material needs to be supplied.

### Means for Solving the Problem

The vapor phase growth apparatus of the present invention is a vapor phase growth apparatus for forming a compound semiconductor thin film on a substrate in a reactor, and includes the following raw material gas supply device. The raw material gas supply device supplies a raw material gas obtained by transporting vapor of an organometallic raw material by a carrier gas into the reactor. The carrier gas is supplied into a container filled with the organometallic raw material, and the carrier gas transports vapor of the organometallic raw material to produce the raw material gas. In a carrier gas supply line upstream of the container, a heater is provided between a mass flow controller that controls the supply amount of the carrier gas and the container storing the organometallic raw material to heat the carrier gas in the carrier gas supply line. In the case where a raw material gas dilution line that supplies the carrier gas into the raw material gas supply line downstream of the container is provided, a second gas heater that heats the carrier gas in the raw material gas dilution line is further provided downstream of the second mass flow controller that controls the supply amount of the carrier gas in the raw material gas dilution line.

### Effects of the Invention

According to the vapor phase growth apparatus of the present invention, even when the vapor pressure of the organometallic raw material is low or when a large amount of the organometallic raw material needs to be supplied, the raw material gas can be stably supplied into the reactor.

### BRIEF DESCRIPTION OF THE DRAWINGS

FIG. 1 is a schematic diagram showing the configuration of a raw material gas supply device in a vapor phase growth apparatus of a first embodiment.

FIG. 2 is a schematic diagram showing the configuration of a raw material gas supply device in a vapor phase growth apparatus of a second embodiment.

FIG. 3 is a schematic diagram showing the configuration of a comparative embodiment to the first embodiment.

FIG. 4 is a schematic diagram showing the configuration of a comparative embodiment to the second embodiment.

FIG. 5 is a schematic diagram of a vapor phase growth apparatus.

### DETAILED DESCRIPTION OF THE PREFERRED EMBODIMENTS

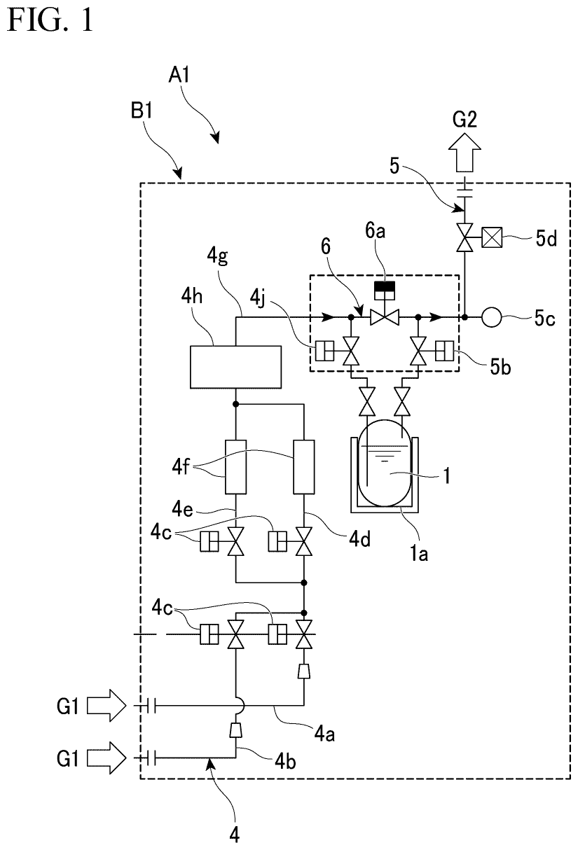

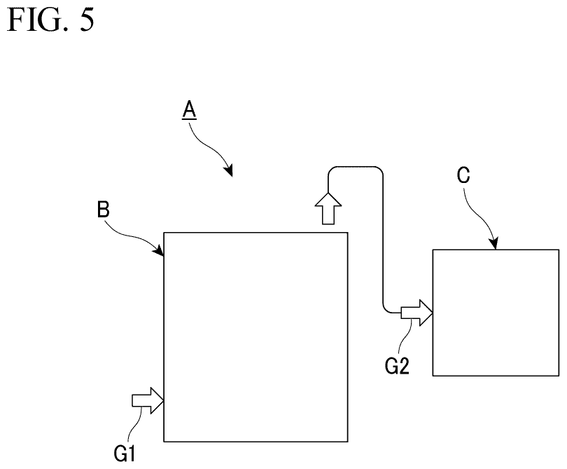

FIG. 1 is a schematic diagram showing the configuration of a raw material gas supply device B1 in a vapor phase growth apparatus A1 of the first embodiment. FIG. 5 is a schematic diagram of the vapor phase growth apparatus A in which the raw material gas supply device B1 is provided. In FIG. 5, the vapor phase growth apparatus A1 and a vapor phase growth apparatus A2 of the first and second embodiments are collectively referred to as the vapor phase growth apparatus A, and the raw material gas supply device B1 and a raw material gas supply device B2 are collectively referred to as the raw material gas supply device B.

The vapor phase growth apparatus A of the present embodiment is a metal organic vapor phase growth apparatus (hereinafter referred to as the MOCVD apparatus) that forms a thin film such as a compound semiconductor on a substrate by the MOCVD (Metal Organic Chemical Vapor Deposition) method. In the vapor phase growth apparatus A, a raw material gas G2 supplied from the raw material gas supply device B is supplied into a reactor (reacting furnace) C, and a compound semiconductor thin film is formed on the substrate in the reactor C.

In the raw material gas supply apparatus B1 shown in FIG. 1, reference numeral 1 denotes a storage container for an organometallic raw material that serves as a supply source of the organometallic raw material gas, reference numeral 4 denotes a carrier gas introduction line for introducing a carrier gas G1 such as hydrogen from a carrier gas introduction section outside the apparatus into the storage container 1, and reference numeral 5 denotes a raw material gas supply line for introducing a gas (raw material gas) G2 containing the organometallic material from the storage container 1 to the outside of the apparatus. The storage container 1 is located within a thermostatic chamber 1a.

The storage container 1 of the organometallic raw material is a supply source of the raw material gas G2. The raw material gas G2 containing an organometallic material, which is a low vapor pressure raw material, is obtained by a bubbling method or a sublimation method using the carrier gas G1 introduced from the carrier gas introduction line 4. The organometallic material in the storage container 1 is heated to a predetermined temperature (100 to 200° C.) in the thermostatic chamber 1a. Note that these temperatures are representative examples, and when MOCVD is used, a lower temperature such as 0° C. may also be used.

The upstream side of the carrier gas introduction line 4 is composed of two systems of first introduction lines 4a and 4b. After the downstream sides of the two first introduction lines 4a and 4b are joined, the carrier gas introduction line 4 branches again into two systems of second introduction lines 4d and 4e. Each of the first introduction lines 4a and 4b and each of the second introduction lines 4d and 4e is provided with a valve 4c. Each of the second introduction lines 4d and 4e is provided with a mass flow controller 4f, which makes it possible to adjust the flow rate of the carrier gas G1 introduced into the storage container 1 through the carrier gas introduction line 4.

The downstream sides of the two second introduction lines 4d and 4e are joined together to form a single third introduction line 4g provided with a gas heater 4h for heating the carrier gas G1 to a predetermined temperature and a valve 4j for opening and closing the flow path of the carrier gas G1 immediately upstream of the storage container 1.

The distance and the internal volume from the mass flow controller 4f to the thermostatic chamber la are preferably as short as possible in order to maintain good responsiveness of the flow rate control. A commercially available heater 4h can be used, but the outlet temperature of the heater 4h drops significantly, so it is desirable to keep the pipe from the heater 4h to the thermostatic chamber 1a as short as possible. In other words, the temperature of the carrier gas G1 introduced from the heater 4h into the storage container 1 is preferably the same as that of the thermostatic chamber 1a. If the temperature of the carrier gas G1 is lower than that of the thermostatic chamber 1a, the organometallic raw material will cool and liquefy. If the temperature of the carrier gas G1 is higher than that of the thermostatic chamber 1a, the organometallic raw material will decompose. The set temperature of the heater 4h varies depending on the type of organometallic raw material and the conditions of use. For example, the present configuration is suitable when using organometallic raw materials that need to be heated to a high temperature, such as europium compounds. Examples of organometallic raw materials suitable for the present configuration include scandium compounds.

The control range of the outlet temperature of the heater 4h is set, for example, in comparison with the temperature of the thermostatic chamber 1a (+40/−0° C.). As an example of the heating temperature, the temperature of the thermostatic chamber 1a that heats the storage container of a europium compound raw material is 130° C. The heating temperature of the gas heater 4h provided upstream of the thermostatic chamber 1a is 150° C. The heating temperature of the gas heater 4h is preferably in a range from the same temperature as the temperature of the thermostatic chamber 1a to about +40° C.

In the first embodiment, the heater 4h is provided in the carrier gas introduction line 4. The mass flow controller 4f is an electronic device and cannot be heated to a high temperature, so the temperature of the flowing carrier gas is set to 80° C. or less. Therefore, the heater 4h is provided downstream of the mass flow controller 4f in the carrier gas introduction line 4, separate from the mass flow controller 4f. In the first embodiment, the gas heater 4h is provided between the mass flow controller 4f and the storage container 1 of the organometallic raw material. Note that the term “gas heater” does not specify the energy of the heater 4h, but means “a heater that heats the gas in a pipe”. The heater 4h may be a heater that uses gas as energy so as to provide a large amount of heat to the carrier gas G1, but may also be, for example, an electric heater.

In the first embodiment, rather than simply heating the carrier gas G1, first, the gas heater 4h is provided as a heater that provides a large amount of heat to the carrier gas G1, and then a pipe heater (not shown) provides a relatively small amount of heat, thereby stably heating the carrier gas G1.

Even if the upstream pipe and valves are heated with a pipe heater, the output of the pipe heater is insufficient to stabilize the temperature of the carrier gas G1 when it reaches the storage container 1 of the organometallic raw material, and the raw material cannot be stably supplied into the reactor.

In the first embodiment, by adding the gas heater 4h to the upstream pipe (carrier gas introduction line 4), it is possible to stabilize the temperature of the carrier gas G1 supplied into the storage container 1 of the organometallic raw material and stably supply the raw material gas into the reactor.

The raw material gas supply line 5 downstream of the storage container 1 is provided with a valve 5b for opening and closing the flow path of the raw material gas G2 immediately downstream of the storage container 1, a pressure gauge 5c for detecting the pressure of the raw material gas G2 downstream of the valve 5b, and a valve 5d for regulating the pressure of the raw material gas G2.

A bypass line 6 having a valve 6a is provided between the third introduction line 4gand the supply line 5, allowing a portion of the carrier gas G1 to be directly added to the raw material gas G2.

The raw material gas supply line 5 is connected to the reactor C (see FIG. 5) which forms a compound semiconductor thin film on a substrate.

In this way, the carrier gas G1 passes through a plurality of valves 4c and has its flow rate controlled by the mass flow controller 4f. After that, the carrier gas G1 is heated to a predetermined temperature by the gas heater 4h and supplied into the storage container 1 of the organometallic raw material through the valve 4j. The organometallic raw material is heated to a predetermined temperature in the thermostatic chamber 1a. Although “a plurality of valves 4c” are used in the present embodiment, the present invention does not necessarily require a plurality of valves.

The raw material gas G2 in which vapor of the organometallic raw material is transported by the carrier gas G1 is supplied into the reactor C (see FIG. 5) through the valve 5b. At this time, the pressure control valve 5d is controlled so that the pressure measured by the pressure gauge 5c becomes the predetermined pressure.

As described above, the vapor phase growth apparatus A1 in the first embodiment includes the raw material gas supplying apparatus B1. The raw material gas supplying apparatus B1 supplies the raw material gas G2 in which the vapor of the organometallic raw material is transported by the carrier gas G1 into the reactor C in order to form a compound semiconductor thin film on a substrate in the reactor C. Nitrogen, hydrogen gas, or the like is supplied as the carrier gas G1 into the storage container 1 filled with the organometallic raw material, and the vapor of the organometallic raw material is transported by the carrier gas G1 to obtain the raw material gas G2. The raw material gas G2 is led out from the storage container 1 and supplied into the reactor C. In the carrier gas introduction line 4 upstream of the storage container 1 in the raw material gas supply device B1, the gas heater 4h for heating the carrier gas G1 is provided between the mass flow controller 4f for controlling the supply amount of the carrier gas G1 and the storage container 1 for storing the organometallic raw material.

According to this configuration, by adding the gas heater 4h to the raw material gas supply line 5, the temperature of the carrier gas G1 supplied into the storage container 1 of the organometallic raw material can be heated to the same temperature as the temperature of the organometallic raw material in the storage container 1. Therefore, even when the vapor pressure of the organometallic raw material is low or when a large amount of the organometallic raw material needs to be supplied, the raw material gas G2 can be stably supplied into the reactor C.

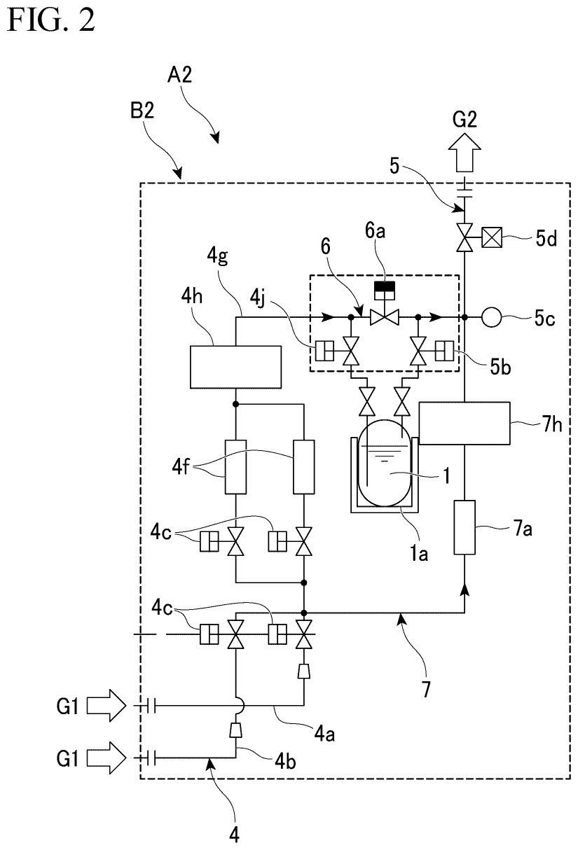

FIG. 2 is a schematic diagram showing the configuration of a raw material gas supply apparatus B2 in the vapor phase growth apparatus A2 of the second embodiment.

The illustrated vapor phase growth apparatus A2 differs from the vapor phase growth apparatus A1 of the first embodiment in that one of the two first introduction lines 4a, 4b branches off from the carrier gas introduction line 4 to be a raw material gas dilution line 7 that is directly connected to the raw material gas supply line 5. Other components that are the same as those in the first embodiment are given the same reference numerals and detailed explanations will be omitted.

The raw material gas dilution line 7 is provided with a second mass flow controller 7a, which makes it possible to adjust the flow rate of the carrier gas G1 supplied into the raw material gas supply line 5 through the raw material gas dilution line 7. The raw material gas dilution line 7 is provided with a second gas heater 7h downstream of the second mass flow controller 7a, which heats the carrier gas G1 to a predetermined temperature.

If the raw material gas G2 in the raw material gas supply line 5 is cooled by the carrier gas G1 supplied from the raw material gas dilution line 7, there is a risk that the raw materials in the gas will liquefy.

In the second embodiment, the second gas heater 7h is provided downstream of the second mass flow controller 7a in the raw material gas dilution line 7 to heat the carrier gas G1 supplied into the raw material gas supply line 5. This makes it possible to prevent condensation of the organometallic raw material due to cooling of the raw material gas G2 in the raw material gas supply line 5.

The vapor phase growth apparatus according to the second embodiment is configured by adding a raw material gas dilution line 7 including the second mass flow controller 7a and the second gas heater 7h to the vapor phase growth apparatus according to the first embodiment. The carrier gas G1 passing through the second gas heater 7h can reduce the concentration of the organometallic raw material in the raw material gas G2 supplied from the valve 5b of the raw material gas supply line 5, and can suppress the subsequent shortage of the raw material supply due to condensation of the organometallic raw material. That is, when the carrier gas G1 heated to a predetermined temperature by the second gas heater 7h is supplied into the raw material gas G2 to dilute the raw material gas G2, it is possible to prevent condensation of the organometallic raw material that occurs when the temperature of the carrier gas G1 is relatively low.

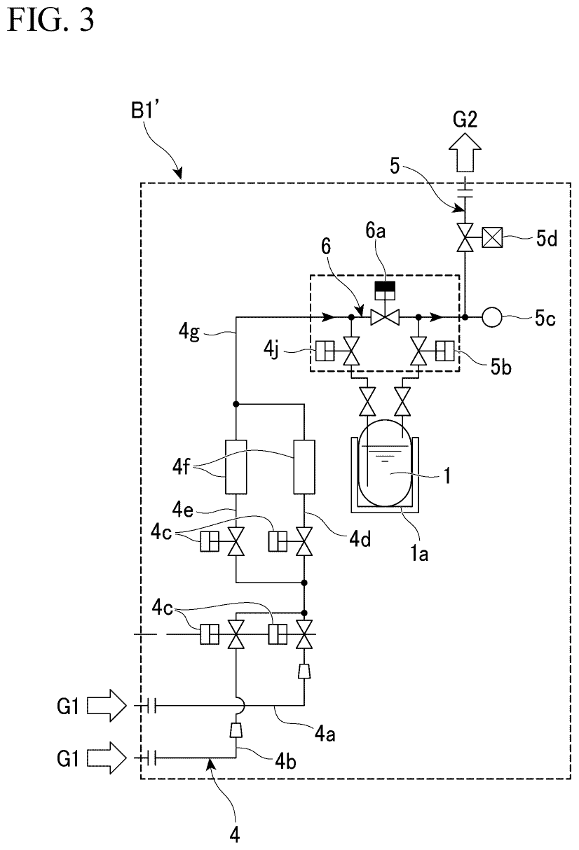

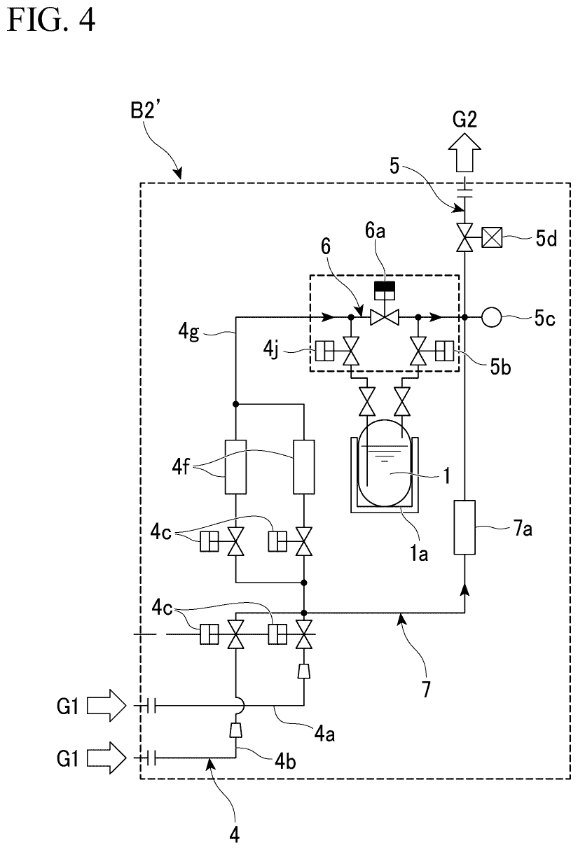

FIG. 3 is a schematic diagram showing the configuration of a comparative embodiment to the first embodiment. FIG. 4 is a schematic diagram showing the configuration of a comparative embodiment to the second embodiment.

In the case of each comparative embodiment, it is possible to heat the carrier gas G1, for example, by the mass flow controller 4f of the carrier gas introduction line 4 or the second mass flow controller 7a of the raw material gas dilution line 7. However, there is a limit to how much the mass flow controllers 4f and 7a, which are electronic devices, can be heated from the outside, and the carrier gas G1 after heating becomes a lower temperature than a predetermined temperature (the same temperature as the temperature of the organometallic raw material in the storage container 1). For this reason, if the carrier gas G1 heated by the mass flow controllers 4f or 7a is introduced into the storage container 1 or merged with the raw material gas G2, it becomes difficult to stably supply the raw material into the reactor C.

In contrast, in the vapor phase growth apparatuses A1 and A2 of each embodiment, the gas heater 4h for heating the carrier gas G1 is provided in the raw material gas supply line 5 between the mass flow controller 4f, which controls the supply amount of the carrier gas G1, and the storage container 1 for storing the organometallic raw material.

With this configuration, by providing the gas heater 4h to the raw material gas supply line 5, it becomes possible to heat the carrier gas G1 supplied into the storage container 1 of the raw material to the same temperature as that of the organometallic raw material in the storage container 1, and the raw material in storage container 1 can be stably supplied into the reactor C.

Furthermore, the vapor phase growth apparatus A2 of the second embodiment is provided with the raw material gas dilution line 7 that directly supplies the carrier gas G1 in the raw material gas G2 led out from the storage container 1, thereby making it possible to reduce the concentration of the organometallic raw material in the raw material gas G2. The raw material gas dilution line 7 is provided with the second gas heater 7h that heats the carrier gas G1 in the raw material gas dilution line 7.

With this configuration, in the raw material gas dilution line 7 that merges with the raw material gas supply line 5 downstream of the storage container 1, the carrier gas G1 is heated to a predetermined temperature by the second gas heater 7h, thereby making it possible to prevent condensation of the organometallic raw material in the raw material gas supply line 5 that may be caused by the carrier gas G1 supplied from the raw material gas dilution line 7.

The configurations in the embodiments above are merely examples of the present invention, and various modifications are possible without departing from the gist of the present invention, such as replacing the components of the embodiments with well-known components.

### EXPLANATION OF SYMBOLS

1 Container
1a Thermostatic chamber
4 Carrier gas introduction line
4f Mass flow controller
4h Gas heater (heater)
5 Raw material gas supply line
7 Raw material gas dilution line
7a Second mass flow controller
7h Second gas heater (second heater)
A, A1, A2 Vapor phase growth apparatus
B, B1, B2 Raw material gas supply apparatus
C Reactor
G1 Carrier gas
G2 Raw material gas

1-2. (canceled)

3. A vapor phase growth apparatus for forming a compound semiconductor thin film on a substrate in a reactor,
wherein the vapor phase growth apparatus comprises a raw material gas supply device in which a raw material gas is obtained by transporting vapor of an organometallic raw material by a carrier gas, and the obtained raw material gas is supplied into the reactor,
wherein,
(1) in the raw material gas supply device, the carrier gas is supplied into a container filled with the organometallic raw material, and transporting vapor of the organometallic raw material by the carrier gas to produce the raw material gas,
(2) the raw material gas supply device is provided with a heater for heating the carrier gas in a carrier gas supply line upstream of the container between the container and a mass flow controller that controls the amount of the carrier gas supplied, and a pipe heater for providing an additional amount of heat to the carrier gas which is smaller than an amount of heat added to the carrier gas by the heater, and
(3) the raw material gas supply device is configured such that the flow path is designed to minimize a pipe length from an outlet of the heater provided with the carrier gas supply line to an inlet of the container, and
wherein the raw material supply device is configured such that the temperature of the carrier gas supplied into the container is heated to substantially the same temperature as the temperature of the raw material in the container.

4. The vapor phase growth apparatus according to claim 3,
wherein the vapor phase growth apparatus further comprises:
(1) a raw material gas dilution line which supplies the carrier gas to a raw material gas supply line downstream of the container; and
(2) a second heater which is provided downstream of a second mass flow controller that controls the supply amount of the carrier gas in the raw material gas dilution line to heat the carrier gas in the raw material gas dilution line, and
(3) the second heater heats the carrier gas which is supplied into the raw material gas dilution line, and thereby preventing condensation of the organometallic raw material in the raw material gas supply line that is caused by decreasing the temperature of the raw material gas in the raw material gas dilution line.
